(19) United States
(12) Patent Application Publication
(10) Pub. No.: US 2025/0085633 A1
(43) Pub. Date: Mar. 13, 2025

(54) THICK FILM RESIST COMPOSITION AND METHOD FOR MANUFACTURING RESIST FILM USING THE SAME

(71) Applicant: Merck Patent GmbH, Darmstadt (DE)

(72) Inventors: Masato SUZUKI, Kakegawa-shi (JP); Hiroshi YANAGITA, Kakegawa-shi (JP); Takayuki SAO, Kakegawa-shi (JP)

(21) Appl. No.: 18/562,363

(22) PCT Filed: May 25, 2022
(86) PCT No.: PCT/EP2022/064144

§ 371 Date: Nov. 20, 2023

(30) Foreign Application Priority Data
May 28, 2021 (JP) 2021-090002

(51) Int. Cl. G03F 7/039; G03F 7/004

(52) U.S. Cl. CPC G03F 7/0397; G03F 7/0045; G03F 7/0048

(57) ABSTRACT

[Problem] To provide a thick film resist composition capable of forming a resist pattern with high rectangularity. [Means for Solution] A thick film resist composition comprising a polymer (A), a deprotecting agent (B), a particular carboxylic acid compound (C) and a solvent (D).

### BACKGROUND OF THE INVENTION

### Technical Field

The present invention relates to a thick film resist composition to be used in manufacturing semiconductor devices, semiconductor integrated circuits and the like, and a method for manufacturing a resist film using the same.

### Background Art

In a process of manufacturing devices such as semiconductor, fine processing by lithographic technique using a resist has generally been employed. The fine processing process comprises forming a thin resist layer on a semiconductor substrate such as a silicon wafer, covering the layer with a mask pattern corresponding to a desired device pattern, exposing the layer with actinic ray such as ultraviolet ray through the mask, developing the exposed layer to obtain a resist pattern, and etching the substrate using the resulting resist pattern as a protective film, thereby forming fine unevenness corresponding to the above-described pattern.

While requiring making the resist pattern finer, there is a demand for a resist pattern that is thicker and has a higher aspect ratio in order to cope with high-energy ion implantation and the like. When forming a thick film resist pattern, unlike the case of a thin film, the performance and process conditions required for the composition are different. Therefore, there are characteristic difficulties that the required shape cannot be formed only by adjusting the viscosity of the thin film resist composition to make it thicker.

Patent Document 1 studies a composition comprising a chemically amplified polymer and a plurality of acid generators for the purpose of obtaining a composition that forms a pattern having a cross-sectional shape close to a rectangle even if it is a thick film.

The shape of the top of the resist pattern becomes important in order to have resistance to subsequent steps such as ion implantation and etching, and a resist composition capable of forming a desired shape is still required.

For thin film resists, studies have been conducted to improve development defects and resist pattern shapes by adding organic acids. For example, Patent Document 2 is conducting studies for the addition of maleic acid or the like to a thin film resist composition for a film thickness of about 0.2 μm.

Patent Document 3 is conducting studies for obtaining a resist pattern of a thick film having a good shape in order to make a magnetic film pattern in a magnetic storage medium.

### PRIOR ART DOCUMENTS

### Patent Documents

[Patent document 1] JP 2018-109701 A
[Patent document 2] JP 2006-106693 A
[Patent document 3] JP 2007-206425 A

### SUMMARY OF THE INVENTION

### Problems to be Solved by the Invention

The present inventors considered that there are one or more problems still need improvement in thick film resist compositions and use thereof. These include, for example, the followings:

Any resist film of thick film cannot be formed. Rectangularity of the resist pattern is insufficient. On the top of the resist pattern wall, a scooped shape exists. The shape near the top of the pattern is bad. In the process after development, problems such as pattern collapse occur. When the thick film resist pattern is used as a mask, the pattern collapse occurs during processing a substrate, so that the substrate cannot be processed as intended. The number of defects is large. The sensitivity obtained using a resist film of thick film is insufficient. Aging stability is poor. The film thickness of a resist film is decreased. The resist film or resist pattern is easily affected by heat. The exposure latitude is small. The resist pattern peels off from a substrate.

The present invention has been made based on the technical background as described above, and provides a thick film resist composition and a method for manufacturing a resist film using the same.

### Means for Solving the Problems

The thick film resist composition according to the present invention comprises a polymer (A), a deprotecting agent (B), a C₄₋₁₂ carboxylic acid compound (C) and a solvent (D),
wherein
the resist film formed from the thick film resist composition has a film thickness of 0.8 to 20 μm; the carboxylic acid compound (C) is an unsaturated hydrocarbon comprising 1, 2 or 3 carboxy groups; and the solvent (D) comprises an organic solvent (D1).

The method for manufacturing a resist film according to the present invention comprises the following steps:
(1) applying the above-mentioned composition above a substrate; and
(2) heating the composition to form a resist film having a film thickness of 0.8 to 20 μm.

### Effects of the Invention

Using the thick film resist composition according to the present invention, it is possible to desire one or more of the following effects.

A resist film of thick film can be formed. A resist pattern with high rectangularity can be formed. The scooped shape on the top of the resist pattern wall can be made smaller. The shape near the top of the pattern can be improved. In the process after development (for example, etching), a resist pattern with high resistance can be obtained. A substrate can be processed using the thick film resist pattern as a mask. The number of defects can be reduced. Good sensitivity can be obtained even with a resist film of thick film. Aging stability is good. Decrease of the film thickness of a resist film can be suppressed. Heat resistance of the resist film or resist pattern is high. The exposure latitude can be increased. It is possible to prevent the resist pattern from peeling off from a substrate.

### BRIEF DESCRIPTION OF THE DRAWINGS

FIG. 1 is a schematic view showing the cross-sectional shape of a resist pattern.

FIG. 2 is a schematic view showing the top of a resist pattern wall.

### DETAILED DESCRIPTION OF THE INVENTION

### Mode for Carrying Out the Invention

### Definition

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has a plural types of repeating units, these repeating units copolymerize. These copolymerization may be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (D) or another component.

Hereinafter, embodiments of the present invention are described in detail.

### Thick Film Resist Composition

The thick film resist composition according to the present invention (hereinafter sometimes referred to as the composition) comprises a polymer (A), a deprotecting agent (B), a C₄₋₁₂ carboxylic acid compound (C) and a solvent (D). The carboxylic acid compound (C) is an unsaturated hydrocarbon comprising 1, 2 or 3 carboxy groups, and the solvent (D) comprises an organic solvent (D1).

The thick film resist composition means a resist composition capable of forming a resist film of thick film. In the present invention, the film thickness of the resist film formed from the thick film resist composition is 0.8 to 20 μm (preferably 1 to 20 μm; more preferably 2 to 15 μm; further preferably 7 to 15 μm; further more preferably 9 to 12 μm).

The viscosity of the composition according to the present invention is preferably 250 to 400 cP (more preferably 280 to 380 cP; further preferably 300 to 350 CP). Here, the viscosity is measured at 25° C. with a capillary viscometer.

The composition according to the present invention is preferably a thick film KrF chemically amplified resist composition or a thick film positive type chemically amplified resist composition; more preferably a thick film KrF positive type chemically amplified resist composition. Here, the term KrF used in the above preferred examples means that a KrF excimer laser is used when exposing a resist film formed from a resist composition.

### (A) Polymer

The composition according to the present invention comprises a polymer (A). The polymer (A) used in the present invention is that reacts with an acid to increase its solubility in an alkaline aqueous solution. Such a polymer is that has, for example, an acid group protected by a protecting group, and when an acid is added from the outside, the protecting group is eliminated and the solubility in an alkaline aqueous solution is increased. Such a polymer can be freely selected from those commonly used in lithography methods.

The polymer (A) preferably comprises a repeating unit selected from the group consisting of repeating units represented by the formulae (P-1), (P-2), (P-3) and (P-4):

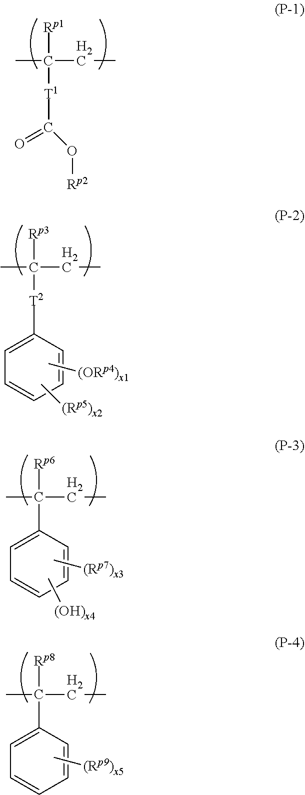

where
R^{p1}, R^{p3}, R^{p6} and R^{p8} are each independently hydrogen or C₁₋₄ alkyl (preferably hydrogen or methyl; more preferably hydrogen).
R^{p2} and R^{p4} are each independently linear, branched or cyclic, C₃₋₁₅ alkyl (where the alkyl can be substituted with fluorine and —CH₂— in the alkyl can be replaced with —O—). Here, the above-mentioned “alkyl substituted with fluorine” means that any H existing in the alkyl is substituted with F. The above-mentioned “substituted with fluorine” means that all or part of H present in the alkyl are substituted with F, and all can be substituted. In one embodiment of the present invention, R^{p2} and R^{p4} are not substituted with fluorine. In one embodiment of the present invention, —CH₂— in the alkyl of R^{p2} and R^{p4} is not replaced with —O—.
R^{p2} is preferably methyl, isopropyl, t-butyl, cyclopentyl, methylcyclopentyl, ethylcyclopentyl, methylcyclohexyl, ethylcyclohexyl, methyladamantyl or ethyladamantyl (more preferably, R^{p2} has a branched or cyclic structure; further preferably, it is t-butyl, ethylcyclopentyl, ethylcyclohexyl or ethyladamantyl; further more preferably t-butyl).
R^{p4} is preferably C₃₋₁₀ (more preferably C₃₋₈; further preferably C₃₋₅; further more preferably t-butyl).
T¹ and T² are each independently a single bond or a C₁₋₁₂ linking group (preferably a single bond). The C₁₋₁₂ linking group of T¹ or T² is each independently alkylene, —COO—Rt-, —O—Rt-, or a linking group consisting of two or more of any of these, and preferably —COO—Rt-. Rt is alkylene or cycloalkylene (more preferably C₁₋₅ alkylene; more preferably —CH₂—, —(CH₂)₂— or —(CH₂)₃—).
R^{p5}, R^{p7} and R^{p9} are each independently C₁₋₅ alkyl (where —CH₂— in the alkyl can be replaced with —O—), preferably methyl or t-butyl, more preferably methyl. In one embodiment of the present invention, —CH₂— in the alkyl of R^{p5}, R^{p7} and R^{p9} is not replaced by —O—.
x1 is 1 to 3 (preferably 1, 2 or 3; more preferably 1).
x2, x3 and x5 are each independently 0 to 2 (preferably 0, 1 or 2; more preferably 0).
x4 is 1 to 2 (preferably 0 or 1; more preferably 1).

Since these repeating units are appropriately compounded according to the purpose, the compounding ratio thereof is not particularly limited, but it is preferable that compounding is made so that the rate of increase in solubility in an alkaline aqueous solution becomes appropriate by means of an acid.

The ratio of the repeating units (P-1) and (P-2) is preferably 5 to 50 mol % (more preferably 10 to 40 mol %) based on the whole repeating units in the polymer.

In the polymer (A), the numbers of the repeating units of the formulae (P-1), (P-2), (P-3) and (P-4) are taken respectively as nₚ₁, nₚ₂, nₚ₃ and nₚ₄. nₚ₁/(nₚ₁+nₚ₂+nₚ₃+nₚ₄) is preferably 0 to 60% (more preferably 1 to 60%; further preferably 5 to 50%; further more preferably 10 to 30%).
nₚ₂/(nₚ₁+nₚ₂+nₚ₃+nₚ₄) is preferably 0 to 60% (more preferably 0 to 50%; further preferably 5 to 50%; further more preferably 5 to 30%). In one embodiment of the present invention, it is also preferable that nₚ₂/(nₚ₁+nₚ₂+nₚ₃+nₚ₄)=0% is satisfied.
nₚ₃/(nₚ₁+nₚ₂+nₚ₃+nₚ₄) is preferably 0 to 90% (more preferably 5 to 80%; further preferably 30 to 80%; further more preferably 50 to 70%).
nₚ₄/(nₚ₁+nₚ₂+nₚ₃+nₚ₄) is preferably 0 to 60% (more preferably 1 to 50%; further preferably 5 to 40%; further more preferably 10 to 30%).

Preferably, nₚ₁+nₚ₂>0% is satisfied, which means that at least one of nₚ₁ and nₚ₂ is larger than 0%. More preferably, nₚ₁ is larger than 0%.

It is preferable that nₚ₁, nₚ₂, nₚ₃ and nₚ₄ satisfy the following formulae:

0%≤nₚ₁/(nₚ₁+nₚ₂+nₚ₃+nₚ₄)≤60%,

0%≤nₚ₂/(nₚ₁+nₚ₂+nₚ₃+nₚ₄)≤60%,

0%≤nₚ₃/(nₚ₁+nₚ₂+nₚ₃+nₚ₄)≤90%, and

0%≤nₚ₄/(nₚ₁+nₚ₂+nₚ₃+nₚ₄)≤60%,

and nₚ₁ and nₚ₂>0% is satisfied.

The polymer (A) can also comprise repeating units other than the repeating units represented by the formulae (P-1), (P-2), (P-3) and (P-4). Here, the total number of all repeating units contained in the polymer (A), which is taken as nₜₒₜₐₗ, preferably satisfies the following formula:

80%≤(nₚ₁+nₚ₂+nₚ₃+nₚ₄)/nₜₒₜₐₗ≤100%.

(nₚ₁+nₚ₂+nₚ₃+nₚ₄)/nₜₒₜₐₗ is more preferably 90 to 100% (further preferably 95 to 100%). It is also one preferred embodiment of the present invention that (nₚ₁+nₚ₂+nₚ₃+nₚ₄)/nₜₒₜₐₗ=100% is satisfied, which means that any repeating unit other than the repeating units represented by the formulae (P-1), (P-2), (P-3) and (P-4) is not contained.

Exemplified embodiments of the polymer (A) are as follows.

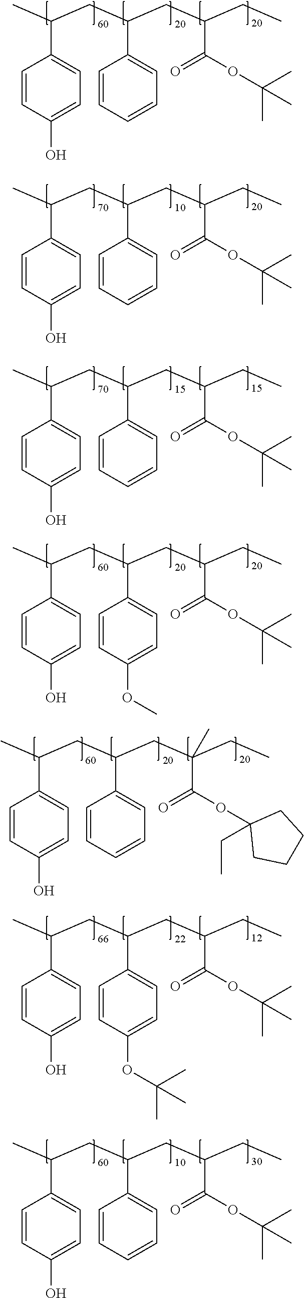

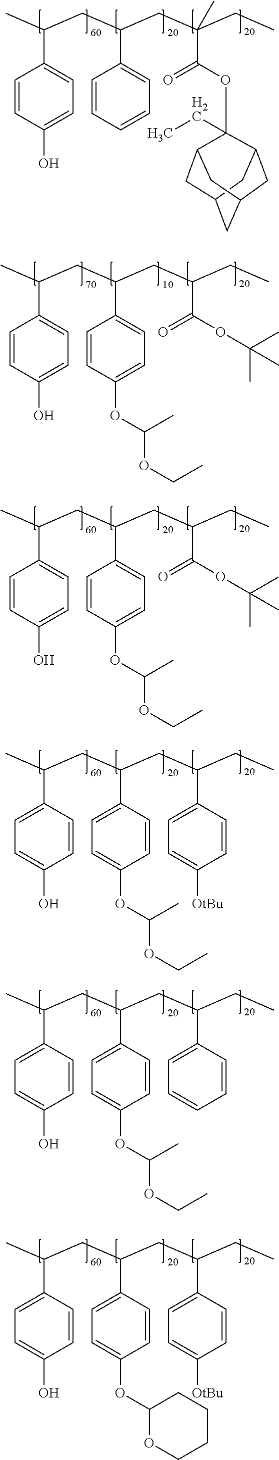

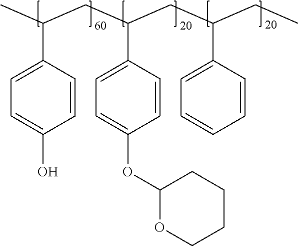

The mass average molecular weight (Mw) of the polymer (A) is preferably 2,000 to 200,000 (more preferably 4,000 to 200,000; further preferably 8,000 to 30,000). Here, the mass average molecular weight is determined by the gel permeation chromatography in terms of polystyrene.

The polymer (A) can be one kind or two or more kinds.

The content of the polymer (A) is preferably 20 to 45 mass % (more preferably 25 to 40 mass %; further preferably 30 to 35 mass %) based on the composition.

### (B) Deprotecting Agent

The composition according to the present invention comprises a deprotecting agent (B). The deprotecting agent plays a role in releasing an acid upon irradiation with light, which acid acts on the polymer (A), and increasing the solubility of the polymer (A) in an alkaline aqueous solution. For example, when the polymer (A) has an acid group protected by a protecting group, the protecting group is made eliminated by the acid. The deprotecting agent used in the composition according to the present invention can be selected from conventionally known ones.

By exposure, the deprotecting agent (B) releases an acid having an acid dissociation constant pka (H₂O) of preferably −20 to 1.4 (more preferably −16 to 1.4; further preferably −16 to 1.2; further more preferably −16 to 1.1).

The deprotecting agent (B) is preferably represented by the formula (B-1) or the formula (B-2).

The formula (B-1) is as follows:

Bⁿ⁺cation Bⁿ⁻anion (B-1)
wherein
Bⁿ⁺cation consists of at least one cation selected from the group consisting of cations represented by the formulae (BC1) to (BC3), and is n valent as a whole (where n is 1 to 3), and
Bⁿ⁻anion consists of at least one anion selected from the group consisting of anions represented by the formulae (BA1) to (BA4), and is n valent as a whole.

The n valent is preferably monovalent or divalent, and more preferably monovalent.

The formula (BC1) is as follows:

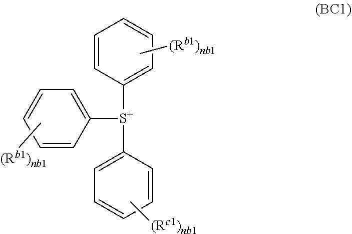

where
R^{b1} is each independently C₁₋₆ alkyl, C₁₋₆ alkoxy, C₆₋₁₂ aryl, C₆₋₁₂ arylthio or C₆₋₁₂ aryloxy (preferably methyl, ethyl, t-butyl, methoxy, ethoxy, phenylthio or phenyloxy; more preferably t-butyl, methoxy, ethoxy, phenylthio or phenyloxy).
nb1 is each independently 0, 1, 2 or 3. It is also a preferred embodiment that all nb1 are 1 and all R^{b1} are identical. It is also a preferred embodiment that nb1 is 0.

Exemplified embodiments of the formula (BC1) are as follows.

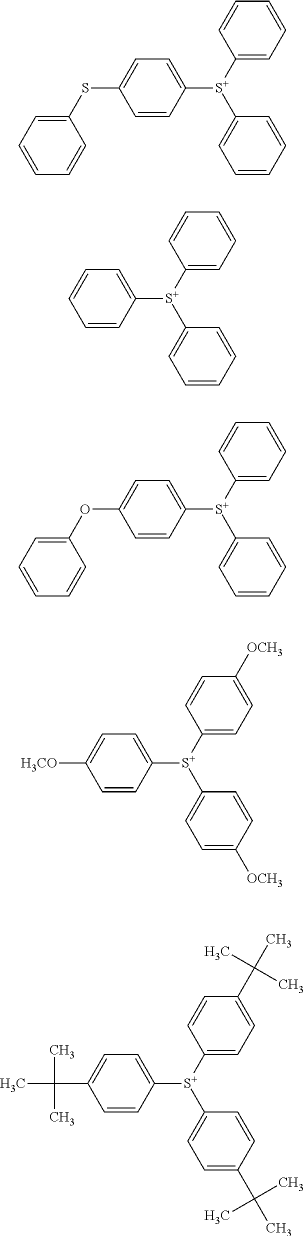 [SMILES: c1ccc(Sc2ccc([S+](c3ccccc3)c3ccccc3)cc2)cc1 ; c1ccc([S+](c2ccccc2)c2ccccc2)cc1 ; c1ccc(Oc2ccc([S+](c3ccccc3)c3ccccc3)cc2)cc1 ; COc1ccc([S+](c2ccc(OC)cc2)c2ccc(OC)cc2)cc1 ; CC(C)(C)c1ccc([S+](c2ccc(C(C)(C)C)cc2)c2ccc(C(C)(C)C)cc2)cc1]

The formula (BC2) is as follows:

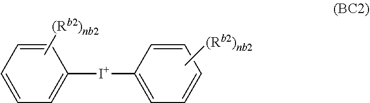

where
R^{b2} is each independently C₁₋₆ alkyl, C₁₋₆ alkoxy or C₆₋₁₂ aryl (R^{b2} is preferably alkyl having a C₄₋₆ branched structure; more preferably t-butyl or 1,1-dimethyl-propyl; further preferably t-butyl). Each R^{b2} in the formula can be identical to or different from each other, and it is more preferable that they are identical. 10
nb2 is each independently 0, 1, 2 or 3, preferably each 1.

Exemplified embodiments of the formula (BC2) are as follows.

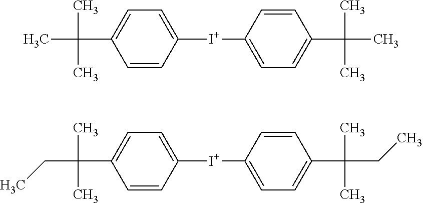

The formula (BC3) is as follows:

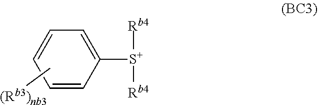

where
R^{b3} is each independently C₁₋₆ alkyl, C₁₋₆ alkoxy or C₆₋₁₂ aryl (preferably methyl, ethyl, methoxy or ethoxy; more preferably methyl or methoxy).
R^{b4} is each independently C₁₋₆ alkyl (preferably methyl or ethyl; more preferably methyl).
nb3 is each independently 0, 1, 2 or 3; more preferably 3.

An exemplified embodiment of the formula (BC3) is as follows.

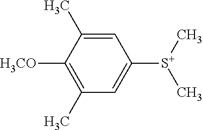

The Bⁿ⁺cation selected from the group consisting of the cations represented by the formula (BC1) or (BC2) is preferable because it exhibits a better effect.

The formula (BA1) is as follows:

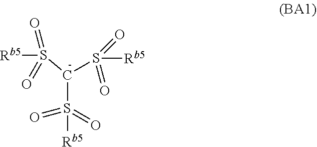

where
R^{b5} is each independently fluorine-substituted C₁₋₆ alkyl, or C₁₋₆ alkyl. For example, —CF₃ means that all of the hydrogen of methyl (C₁) are substituted with fluorine. Preferably all of the hydrogen present in the fluorine-substituted C₁₋₆ alkyl is substituted with fluorine. The alkyl moiety of R^{b5} is preferably methyl, ethyl or t-butyl (more preferably methyl). In a preferred embodiment, R^{b5} is preferably a fluorine-substituted alkyl, more preferably —CF₃.

An exemplified embodiment of the formula (BA1) is as follows.

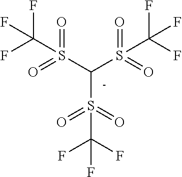 [SMILES: O=S(=O)([C-](S(=O)(=O)C(F)(F)F)S(=O)(=O)C(F)(F)F)C(F)(F)F]

The formula (BA2) is as follows:

R^{b6}—SO₃⁻ (BA2)

where
R^{b6} is fluorine-substituted C₁₋₆ alkyl, fluorine-substituted C₁₋₆ alkoxy, fluorine-substituted C₆₋₁₂ aryl, fluorine-substituted C₂₋₁₂ acyl or fluorine-substituted C₆₋₁₂ alkoxyaryl (preferably fluorine-substituted C₂₋₆ alkyl; more preferably fluorine-substituted C₂₋₃ alkyl; further preferably fluorine-substituted C₃ alkyl). In the fluorine-substituted alkyl of R^{b6}, an embodiment in which all the hydrogen present in the alkyl moiety are substituted with fluorine is preferable. The alkyl moiety of R^{b6} is preferably methyl, ethyl, propyl, butyl or pentyl (more preferably propyl, butyl or pentyl; further preferably butyl). The alkyl moiety of R^{b6} is preferably linear.

Exemplified embodiments of the formula (BA2) are as follows.
C₄F₉SO₃⁻, C₃F₇SO₃⁻

The formula (BA3) is as follows:)

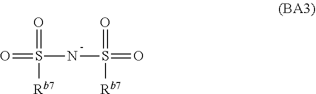

where
R^{b7} is each independently fluorine-substituted C₁₋₆ alkyl, fluorine-substituted C₁₋₆ alkoxy, fluorine-substituted C₆₋₁₂ aryl, fluorine-substituted C₂₋₁₂ acyl or fluorine-substituted C₆₋₁₂ alkoxyaryl (preferably fluorine-substituted C₂₋₆ alkyl). The alkyl moiety of R^{b7} is preferably methyl, ethyl, propyl, butyl or pentyl (more preferably methyl, ethyl or butyl; further preferably butyl). The alkyl moiety of R^{b7} is preferably linear.

Here, two R^{b7} can be bonded to each other to form a fluorine-substituted heterocyclic structure. In this case, the heterocycle can be monocyclic or polycyclic, but preferably is a monocyclic structure having 5 to 8 members.

Exemplified embodiments of the formula (BA3) are as follows.

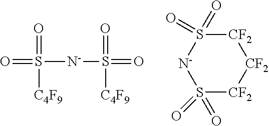

The formula (BA4) is as follows:

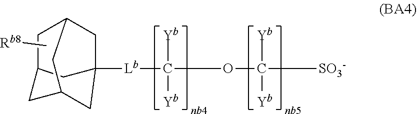

where
R^{b8} is hydrogen, C₁₋₆ alkyl, C₁₋₆ alkoxy or hydroxy (preferably hydrogen, methyl, ethyl, methoxy or hydroxy; more preferably hydrogen or hydroxy).
L^{b} is carbonyl, oxy or carbonyloxy (preferably carbonyl or carbonyloxy; more preferably carbonyl).
Y^{b} is each independently hydrogen or fluorine, preferably at least 1 or more are fluorine.
nb4 is an integer of 0 to 10, preferably 0.
nb5 is an integer of 0 to 21, preferably 4, 5 or 6.

Exemplified embodiments of the formula (BA4) are as follows.

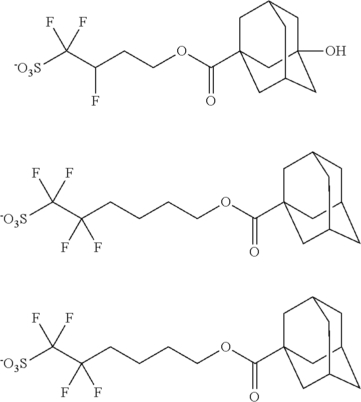

The Bⁿ⁻anion selected from the group consisting of the anions represented by the formula (BA2) or (BA3) is preferable because it exhibits a better effect. An embodiment in which the composition according to the present invention contains two kinds of deprotecting agents (B), each of which contains an anion represented by (BA2) and an anion represented by (BA3) as anions is preferable.

The formula (B-2) is as follows:

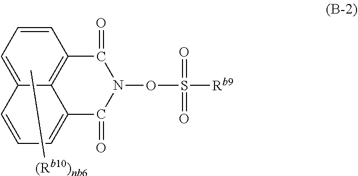

where
R^{b9} is fluorine-substituted C₁₋₅ alkyl (preferably, C₁₋₄ alkyl in which all hydrogen are substituted with fluorine; more preferably C₁ or C₄ alkyl in which all hydrogen are substituted with fluorine).
R^{b10} is each independently C₃₋₁₀ alkenyl or alkynyl (where CH₃— in the alkenyl and alkynyl can be replaced with phenyl, and —CH₂— in the alkenyl and alkynyl can be replaced with at least one of —C(═O)—, —O— or phenylene), C₂₋₁₀ thioalkyl, C₅₋₁₀ saturated heterocycle (preferably C₃₋₁₂ alkenyl or alkynyl, or C₃₋₅ thioalkyl, C₅₋₆ saturated heterocycle; more preferably —C≡C—CH₂—CH₂—CH₂—CH₃, —CH═CH—C(═O)—O-tBu, —CH═CH-Ph, —S—CH(CH₃)₂, —CH═CH-Ph-O—CH(CH₃)(CH₂CH₃) and piperidine). Here, tBu means t-butyl and Ph means phenylene or phenyl. In the present invention, alkenyl means a monovalent group having one or more double bonds (preferably one). Similarly, alkynyl means a monovalent group having one or more triple bonds (preferably one).
nb6 is 0, 1 or 2 (preferably 0 or 1; more preferably 0). It is also a preferred embodiment that nb6=1 is satisfied.

Exemplified embodiments of the formula (B-2) include the followings.

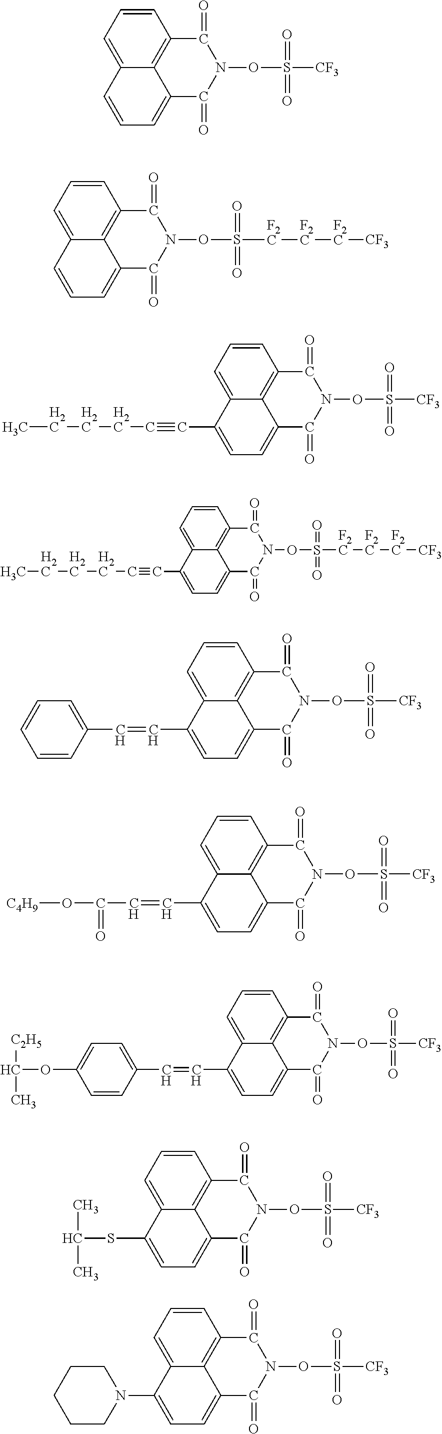

The molecular weight of the deprotecting agent (B) is preferably 400 to 2,500, more preferably 400 to 1,500.

The deprotecting agent (B) can be one kind or two or more kinds, and a combination of two kinds is also a preferable embodiment.

The content of the deprotecting agent (B) is preferably 0.05 to 10 mass % (more preferably 0.1 to 5 mass %; further preferably 0.5 to 2 mass %) based on the total mass of the polymer (A). Although describing for clarity, when two deprotecting agents (B) are used in combination, the above content means the sum of the two deprotecting agents (B).

### (C) Carboxylic Acid Compound

The composition according to the present invention comprises a C₄₋₁₂ carboxylic acid compound (C). The carbon number of the carboxylic acid compound (C) is counted including the carboxylic acid part. For example, fumaric acid corresponds to a C₄ carboxylic acid compound (C). The carboxylic acid compound (C) is an unsaturated hydrocarbon comprising 1, 2 or 3 (preferably 1 or 2) carboxy groups. The carboxylic acid compound (C) has a double bond or a triple bond between carbon atoms, and preferably has at least one double bond between carbon atoms.

The pKa1 (H₂O) of the carboxylic acid compound (C) is preferably 1.00 to 6.00 (more preferably 1.80 to 3.50; further preferably 2.25 to 2.90). Although describing for clarity, as the pKa of the carboxylic acid compound (C), the one in the first stage (pKa1) is used, and if there is only one pka, it is used.

By containing the carboxylic acid compound (C), the composition according to the present invention can make the shape of the top of the resist pattern, which is described later, to be one of small scoop and high rectangularity. Although not to be bound by theory, it is assumed that the unsaturated fatty acid that is contained in the carboxylic acid compound (C) is not easily decomposed by heat during resist film formation or exposure and its acidity is high (pKa1 is low), which makes it possible to control the pattern shape. Although not to be bound by theory, it is assumed that the carboxylic acid compound (C) quenches environmental-origin amines and it is possible to prevent the environmental-origin amines from inhibiting the action of the acid (for example, derived from the deprotecting agent (B)) changing the alkali solubility of the polymer (A). Although not to be bound by theory, it is assumed that since the molecular weight of the carboxylic acid compound (C) is small, the carboxylic acid compound (C) can be unevenly distributed near the film surface as the solvent evaporates by heating at the time of film formation, and the environmental amines near the film surface where the influence tends to be large can be quenched.

In a preferred embodiment, the carboxylic acid compound (C) is an aromatic carboxylic acid (C-1) represented by the formula (c-1) or an aliphatic carboxylic acid (C-2) represented by the formula (c-2).

The formula (c-1) is as follows:

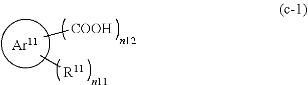

where
Ar¹¹ is a C₅₋₁₀ aromatic hydrocarbon ring, and can be monocyclic or polycyclic. Ar¹¹ is preferably benzene or naphthalene (more preferably benzene).
R¹¹ is OH or NH₂, preferably OH.
n11 is 0 or 1 (preferably 1).
n12 is 0, 1 or 2 (preferably 1).

Exemplified embodiments of the aromatic carboxylic acid (C-1) include benzoic acid, 2-hydroxybenzoic acid (salicylic acid), 3-hydroxybenzoic acid, 4-hydroxybenzoic acid and the like, and 2-hydroxybenzoic acid is preferable.

The formula (c-2) is as follows:

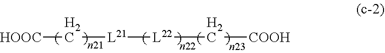

where
L²¹ is —C═C— or —C≡C—, preferably —C═C—.
L²² is —C═C— or —C≡C—, preferably —C═C—.
n21 is 0, 1, 2 or 3 (preferably 0 or 1; more preferably 0).
n22 is 0 or 1, preferably 0.
n23 is 0, 1, 2 or 3 (preferably 0 or 1; more preferably 0).

Exemplified embodiments of the aliphatic carboxylic acid (C-2) include fumaric acid, maleic acid and the like, preferably fumaric acid.

The molecular weight of the carboxylic acid compound (C) is preferably 80 to 200, more preferably 90 to 140.

The carboxylic acid compound (C) can be one kind or two or more kinds.

The content of the carboxylic acid compound (C) is preferably 0.01 to 5 mass % (more preferably 0.03 to 4 mass %; further preferably 0.10 to 2 mass %; further more preferably 0.12 to 1.00 mass %) based on the polymer (A).

### (D) Solvent

The composition according to the present invention comprises a solvent (D). The solvent (D) comprises an organic solvent (D1). The content of the organic solvent (D1) is preferably 80 to 100 mass % (more preferably 95 to 100 mass %; further preferably 98 to 100 mass %; further more preferably 100 mass %) based on the solvent (D).

The organic solvent (D1) is not particularly limited as long as it can dissolve each component, and can be freely selected from those generally used in the lithography method. Exemplified embodiments thereof include ethylene glycol monoalkyl ethers such as ethylene glycol monomethyl ether and ethylene glycol monoethyl ether; ethylene glycol monoalkyl ether acetates such as ethylene glycol monomethyl ether acetate and ethylene glycol monoethyl ether acetate; propylene glycol monoalkyl ethers such as propylene glycol monomethyl ether (hereinafter sometimes referred to as PGME) and propylene glycol monoethyl ether; propylene glycol monoalkyl ether acetates such as propylene glycol monomethyl ether acetate (hereinafter sometimes referred to as PGMEA) and propylene glycol monoethyl ether acetate; lactates such as methyl lactate and ethyl lactate (hereinafter sometimes referred to as EL); aromatic hydrocarbons such as toluene and xylene; amides such as N,N-dimethylacetamide and N-methylpyrrolidone; lactones such as γ-butyrolactone, and the like. These can be used alone or in combination of two or more of any of these.

In a preferred embodiment, the solvent (D) comprises, as the organic solvent (D1), at least one selected from the group consisting of ethylene glycol monoalkyl ethers, ethylene glycol monoalkyl ether acetates, propylene glycol monoalkyl ethers, propylene glycol monoalkyl ether acetates, lactates, aromatic hydrocarbons, amides and lactones.

In relation to other layers or films, it is also one embodiment that the solvent (D) substantially contains no water. For example, the amount of water in the whole solvent (D) is preferably 0.1 mass % or less, more preferably 0.01 mass % or less, and further preferably 0.001 mass % or less. It is also a preferred embodiment that the solvent (D) contains no water (0 mass %).

The content of the solvent (D) is preferably 50 to 80 mass % (more preferably 55 to 75 mass %; further preferably 60 to 70 mass %) based on the composition.

### (E) Quencher

The composition according to the present invention comprises a quencher (E). The quencher (E) has the effects of suppressing the diffusion of the acid derived from the deprotecting agent (B) and generated at the exposed portion, and of suppressing the deactivation of the acid on the surface of the resist film due to the components such as amines contained in the air. Furthermore, the pH of the composition can be controlled by adjusting the amount of the quencher (E). The structure of the quencher (E) is different from that of the carboxylic acid compound (C).

The quencher (E) is preferably an amine compound (E1) or a carboxylate (E2). When the quencher (E) is a carboxylate (E2), it releases an acid upon irradiation with light, but the acid does not act directly on the polymer. In this respect, it differs from the deprotecting agent (B), which has a direct action on the polymer by eliminating the protecting group of the polymer by the released acid.

Examples of the amine compound (E1) include the followings:
(i) ammonia;
(ii) primary aliphatic amines having 1 to 16 carbon atoms and derivatives thereof, such as methylamine, ethylamine, isopropylamine, tert-butylamine, cyclohexylamine, ethylenediamine and tetraethylenediamine;
(iii) secondary aliphatic amines having 2 to 32 carbon atoms and derivatives thereof, such as dimethylamine, diethylamine, methylethylamine, dicyclohexylamine and N,N-dimethylmethylenediamine;
(iv) tertiary aliphatic amines having 3 to 48 carbon atoms and derivatives thereof, such as trimethylamine, triethylamine, dimethylethylamine, tricyclohexylamine, N,N,N′,N′-tetramethylethylenediamine, N,N,N′,N″,N″-pentamethyldiethylenetriamine, tris[2-(dimethylamino)ethyl]amine and tris[2-(2-methoxyethoxy)ethyl]amine;
(v) aromatic amines having 6 to 30 carbon atoms and derivatives thereof, such as aniline, benzylamine, naphthylamine, N-methylaniline, 2-methylaniline, 4-aminobenzoic acid and phenylalanine; and
(vi) heterocyclic amines having 5 to 30 carbon atoms and derivatives thereof, such as pyrrole, oxazole, thiazol, imidazole, 4-methylimidazole, pyridine, methylpyridine and butylpyridine.

As the amine compound (E1), (iv) is a preferred embodiment. In (iv), tris[2-(2-methoxyethoxy)ethyl] is a preferred embodiment.

The molecular weight of the amine compound (E1) is preferably 17 to 500, more preferably 60 to 400.

The base dissociation constant pKb (H₂O) of the amine compound (E1) is preferably-12 to 5, more preferably 1 to 4.

The carboxylate (E2) releases, upon exposure, an acid having an acid dissociation constant pka (H₂O) of preferably 1.5 to 8, more preferably 1.5 to 5.

In one preferred embodiment, the carboxylate (E2) is represented by the formula (e-2):

C^{m+}cation C^{m-}anion (e-2)

wherein
c^{m+}cation consists of at least one cation selected from the group consisting of the cations represented by the formulae (EC1) and (EC2), and is m valent as a whole (where m is 1 to 3).
c^{m-}anion consists of at least one anion represented by the formula (EA), and is m valent as a whole.

The m valent is preferably monovalent or divalent, and more preferably monovalent.

The formula (EC1) is as follows:

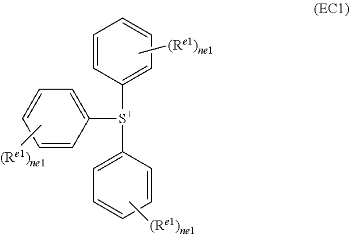

where
R^{e1} is each independently C₁₋₆ alkyl, C₁₋₆ alkoxy or C₆₋₁₂ aryl (preferably methyl, ethyl, t-butyl, methoxy, ethoxy, phenylthio or phenyloxy; more preferably t-butyl, methoxy, ethoxy, phenylthio, phenyloxy; further preferably t-butyl or methoxy).
ne1 is each independently 0, 1, 2 or 3. It is also a preferred embodiment that all ne1 are 1 and all R^{e1} are identical. It is also a preferred embodiment that ne1 is 0.

Exemplified embodiments of the formula (EC1) are as follows:

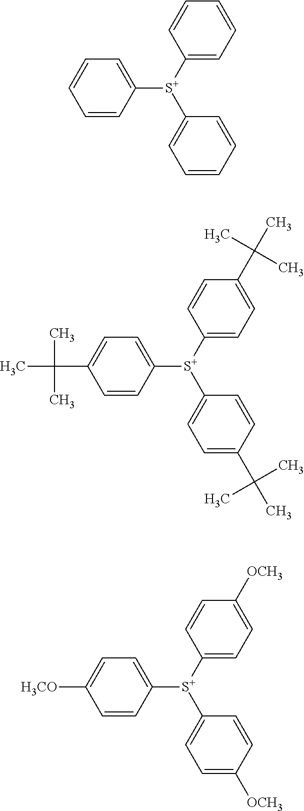 [SMILES: c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; COc1ccc([S+](c2ccc(OC)cc2)c2ccc(OC)cc2)cc1]

The formula (EC2) is as follows:

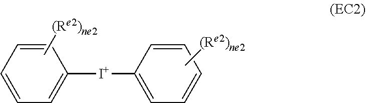

where,
R^{e2} is each independently C₁₋₆ alkyl, C₁₋₆ alkoxy or C₆₋₁₂ aryl (R^{e2} is preferably alkyl having a C₄₋₆ branched structure; more preferably t-butyl or 1,1-dimethyl-propyl; more preferably t-butyl). Each R^{e2} can be identical to or different from each other, and it is more preferable that they are identical.
ne2 is each independently 0, 1, 2 or 3, preferably 1.

Exemplified embodiments of the formula (EC2) are as follows:

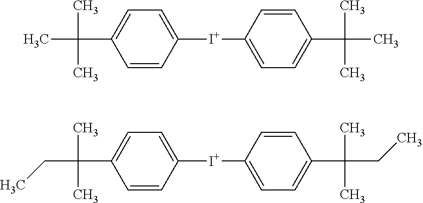

The formula (EA) is as follows:

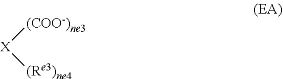

where
X is a C₁₋₂₀ hydrocarbon group, which can be any of linear, branched or cyclic, but is preferably linear or cyclic. In the case of linear, it is preferably C₁₋₄ (more preferably C₁₋₂), and preferably has one double bond in the chain or is saturated. When it is cyclic, it can be monocyclic aromatic ring, or a saturated monocyclic or polycyclic ring. When it is monocyclic, it is preferably a 6-membered ring, and when it is polycyclic, it is preferably an adamantane ring. X is preferably methyl, ethyl, propyl, butyl, ethane, phenyl, cyclohexane or adamantane (more preferably methyl, phenyl or cyclohexane; more preferably phenyl).
R^{e3} is each independently OH, C₁₋₆ alkyl or C₆₋₁₀ aryl (preferably OH, methyl, ethyl, 1-propyl, 2-propyl, t-butyl or phenyl; more preferably OH).
ne3 is 1, 2 or 3 (preferably 1 or 2; more preferably 1).
ne4 is 0, 1 or 2 (preferably 0 or 1; more preferably 1).

Exemplified embodiments of the formula (EA) are as follows.

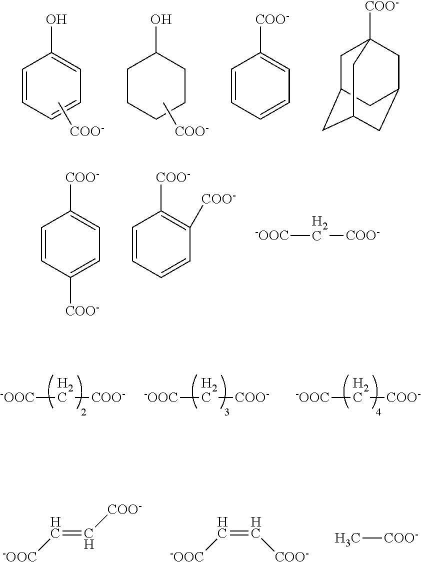

The molecular weight of the carboxylate (E2) is preferably 300 to 1,400, more preferably 300 to 1,200.

The quencher (E) can be one type or two or more types.

The content of the quencher (E) is preferably 0.001 to 5 mass % (more preferably 0.05 to 2 mass %; further preferably 0.01 to 1 mass %) based on the polymer (A).

### (F) Surfactant

The composition according to the present invention can comprise a surfactant (F). By the surfactant (F), the coatability of the composition can be improved. Examples of the surfactant (F) include nonionic surfactants, anionic surfactants, amphoteric surfactants and the like.

Examples of the nonionic surfactant include, polyoxyethylene alkyl ethers such as polyoxyethylene lauryl ether, polyoxyethylene oleyl ether and polyoxyethylene cetyl ether, polyoxyethylene fatty acid diesters, polyoxyethylene fatty acid monoesters, polyoxyethylene polyoxypropylene block polymer, acetylene alcohol, acetylene glycol, polyethoxylate of acetylene alcohol, acetylene glycol derivatives such as polyethoxylate of acetylene glycol, fluorine-containing surfactants, for example, FLUORAD (trade name, 3M Japan), MEGAFACE (trade name: DIC), SURFLON (trade name, AGC), or organosiloxane surfactants, for example, KF-53 (trade name, Shin-Etsu Chemical), and the like. Examples of the acetylene glycol include 3-methyl-1-butyne-3-ol, 3-methyl-1-pentyn-3-ol, 3,6-dimethyl-4-octyne-3,6-diol, 2,4,7,9-tetramethyl-5-decyne-4,7-diol, 3,5-dimethyl-1-hexyne-3-ol, 2,5-dimethyl-3-hexyne-2,5-diol, 2,5-dimethyl-2,5-hexane-diol, and the like.

Examples of the anionic surfactant include ammonium salt or organic amine salt of alkyl diphenyl ether disulfonic acid, ammonium salt or organic amine salt of alkyl diphenyl ether sulfonic acid, ammonium salt or organic amine salt of alkyl benzene sulfonic acid, ammonium salt or organic amine salt of polyoxyethylene alkyl ether sulfuric acid, ammonium salt or organic amine salt of alkyl sulfuric acid, and the like.

Examples of the amphoteric surfactant include 2-alkyl-N-carboxymethyl-N-hydroxyethyl imidazolium betaine, lauric acid amide propyl hydroxysulfone betaine, and the like.

The surfactant (F) can be used alone or in combination of two or more of any of these.

The content of the surfactant (F) is preferably 0.01 to 5 mass %, more preferably 0.05 to 1 mass %, based on the polymer (A).

### (G) Additive

The composition according to the present invention can comprise an additive (G) other than (A) to (F). The additive (G) is preferably at least one selected from the group consisting of a surface smoothing agent, a plasticizer, a dye, a contrast enhancer, an acid, a base, a radical generator, a substrate adhesion enhancer and an antifoaming agent.

The content of the additive (G) is preferably 0.01 to 10 mass %, more preferably 0.1 to 2 mass %, based on the polymer (A). It is also a preferred embodiment of the composition according to the present invention that no additive (G) is contained (0 mass %).

### Method for Manufacturing a Resist Film

The method for manufacturing a resist film according to the present invention comprises the following steps:
(1) applying the composition according to the present invention above a substrate; and
(2) heating the composition to form a resist film having a film thickness of 0.8 to 20 μm.

Hereinafter, one embodiment of the manufacturing method according to the present invention is described.

### Step (1)

The composition according to the present invention is applied above a substrate (for example, a silicon/silicon dioxide coated substrate, a silicon nitride substrate, a silicon wafer substrate, a glass substrate, an ITO substrate, and the like) by an appropriate method. In the present invention, the “above” includes the case where a layer is formed directly on a substrate and the case where a layer is formed on a substrate via another layer. For example, a planarization film or resist underlayer can be formed immediately above a substrate, and the composition according to the present invention can be applied immediately above the film. An embodiment in which the composition according to the present invention is applied immediately above (without intervening other layer) is more preferable. The application method is not particularly limited, and examples thereof include a method using a spinner or a coater.

### Step (2)

After application of the composition, a resist film having a film thickness of 0.8 to 20 μm is formed by heating. The heating in the step (2) is performed, for example, by a hot plate. The heating temperature is preferably 100 to 250° C. (more preferably 100 to 200° C.; further preferably 100 to 160° C.). The temperature here is a temperature of heating atmosphere, for example, that of a heating surface of a hot plate. The heating time is preferably 30 to 300 seconds (more preferably 60 to 240 seconds). The heating is preferably performed in an air or a nitrogen gas atmosphere.

The film thickness of the resist film is selected depending on the purpose, but when the composition according to the present invention is used, a pattern having a more excellent shape can be obtained when a coating film having thick film thickness is formed. For this reason, the thickness of the resist film is preferably thicker, for example, preferably 1 to 20 μm (more preferably 2 to 15 μm; further preferably 7 to 15 μm; further more preferably 9 to 12 μm).

A resist pattern can be manufactured by the method further comprising the following steps:
(3) exposing the resist film; and
(4) developing the resist film.

Although describing for clarity, the steps (1) and (2) are performed before the step (3). The numbers in parentheses indicating the step mean the order. The same applies hereinafter.

### Step (3)

The resist film is exposed through a predetermined mask. The wavelength of light to be used for exposure is not particularly limited, but it is preferable to expose with light having a wavelength of 13.5 to 248 nm. In particular, KrF excimer laser (wavelength: 248 nm), ArF excimer laser (wavelength: 193 nm), extreme ultraviolet ray (wavelength: 13.5 nm), or the like can be used, and KrF excimer laser is preferable. These wavelengths allow a range of ±1%. After exposure, post exposure bake (PEG) can also be performed, as necessary. The temperature for PEG is preferably 80 to 150° C.; more preferably 100 to 140° C., and the heating time is 0.3 to 5 minutes; preferably 0.5 to 2 minutes.

### Step (4)

The exposed resist film is developed with a developer. As the developing method, a method conventionally used for developing a photoresist, such as a paddle developing method, an immersion developing method, or a swinging immersion developing method, can be used. As the developer, aqueous solution 10 containing inorganic alkalis, such as sodium hydroxide, potassium hydroxide, sodium carbonate and sodium silicate; organic amines, such as ammonia, ethylamine, propylamine, diethylamine, diethylaminoethanol and triethylamine; quaternary amines, such as 15 tetramethylammonium hydroxide (TMAH); and the like are used, and a 2.38 mass % TMAH aqueous solution is preferable. A surfactant can be further added to the developer. The temperature of the developer is preferably 5 to 50° C., more preferably 25 to 40° C., and 20 the development time is preferably 10 to 300 seconds, more preferably 30 to 60 seconds. After development, washing with water or rinsing treatment can also be performed, as necessary. When a positive type resist composition is used, the exposed region is removed by 25 development to form a resist pattern. The resist pattern can also be further made finer, for example, using a shrink material.

When a thick film resist pattern is formed using a chemically amplified resist, a scooped part may be generated at the top of resist pattern wall, especially when the aspect ratio is high (details of the scooped part are explained using Figures in Examples).

In a preferred embodiment, the distance between the perpendicular line drawn from the end point of the top of the resist pattern down to the substrate and the perpendicular line drawn from the most scooped point on the side surface of the resist pattern down to the substrate (hereinafter sometimes referred to as the width of bite) is 50 nm or less (more preferably 0 to 45 nm; further preferably 0 to 20 nm; further more preferably 0 to 1 nm). In the present invention, occurrence of the scooped part can be suppressed and a pattern with high rectangularity can be formed. Since the scooped part can be suppressed, resistance of the pattern can be strengthened in the subsequent steps, which is advantageous.

A processed substrate can be manufactured by a method further comprising the following step:
(5) processing using the resist pattern as a mask.

In one embodiment of the present invention, it is preferable not to apply metal (for example, plating) between the patterns (trenches) of the resist pattern. That is, an embodiment in which no metal (for example, plating) is filled between the resist patterns is preferable.

### Step (5)

The formed resist pattern is preferably used for processing a underlayer film or substrate (more preferably substrate). In particular, with the resist pattern as a mask, various substrates that become a base can be processed using a dry etching method, a wet etching method, an ion implantation method, a metal plating method, or the like. It is a more preferable embodiment to etch the substrate by a dry etching method using the resist pattern of the present invention as a mask. Since the resist pattern according to the present invention can increase the film thickness, it can also be used for substrate processing using an ion implantation method.

When processing an underlayer film using a resist pattern, the processing can be performed in stages. For example, a BARC layer can be processed using a resist pattern, a SOC film can be processed using the BARC pattern, and a substrate can be processed using the SOC pattern.

Thereafter, if necessary, the substrate is further processed, a step of forming a wiring on the processed substrate is preferably conducted, and a device can be manufactured. For these processing, known methods can be applied. If necessary, the substrate is cut into chips, which are connected to a lead frame and packaged with resin. In the present invention, this packaged product is referred to as the device. Examples of the device include a semiconductor device, a liquid crystal display device, an organic EL display device, a plasma display device, and a solar cell device, preferably a semiconductor.

Using the thick film resist composition of the present invention, it is possible to control the pattern shape of the resist pattern to be formed. Therefore, from another viewpoint, the present invention provides the following methods:
a method for controlling the pattern shape by forming a resist pattern using the thick film resist composition of the present invention;
a method for controlling the width of bite of a resist pattern by forming a resist pattern using the thick film resist composition of the present invention (preferably, a method for reducing the width of bite); and
a method of controlling the width of bite of a resist pattern to 50 nm or less by forming a resist pattern using the thick film resist composition of the present invention.

The details of the thick film resist composition in the above methods are as described above. The details of the methods for manufacturing the resist film, the resist pattern, the processed substrate and the device are as described above.

### Example

The present invention is described below with reference to several examples. In addition, the embodiments of the present invention are not limited only to these examples.

### Preparation of Composition 1

PGME and PGMEA are mixed at a mass ratio of 70:30 (=PGME:PGMEA) to obtain a mixed solvent. Into this mixed solvent (66.0 mass parts), the polymer A1 (33.451 mass parts), the deprotecting agent B1 (0.067 mass parts), the deprotecting agent B2 (0.375 mass parts), the quencher E1 (0.007 mass parts), the carboxylic acid compound C1 (0.05 mass parts) and the surfactant F1 (0.051 mass parts) are added, and the mixture is stirred at room temperature for 30 minutes to obtain a solution. It is visually confirmed that each component is completely dissolved. The obtained solution is filtered through a 0.05 μm filter to obtain Composition 1.
polymer A1: p-hydroxystyrene/styrene/t-butyl acrylate copolymer (Mw=20,000, random copolymerization)

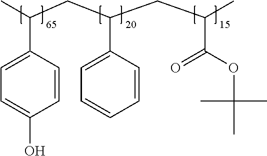

deprotecting agent B1: the compound shown below (Gokyo Food & Chemical)

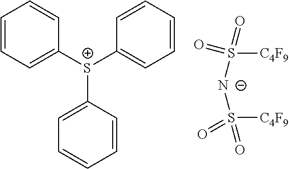

deprotecting agent B2: the compound shown below (Gokyo Food & Chemical)

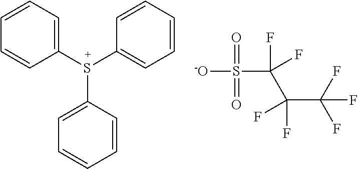

carboxylic acid compound C1: 2-hydroxybenzoic acid
quencher E1: tris[2-(2-methoxyethoxy)ethyl]amine
surfactant F1: MEGAFACE R-2011 (DIC)

### Preparation of Compositions 2 to 5 and Comparative Compositions 1 to 5

Compositions 2 to 5 and Comparative Compositions 1 to 5 are prepared in the same manner as the above Composition 1 except that the carboxylic acid compound C₁ is changed to the compound shown in Table 1 and the compounding amount of the compound is changed so that the molar ratio with respect to the polymer A1 is the same relation as that of Composition 1.

In Table 1, in the parentheses next to the carboxylic acid compound, each pKa1 is shown, and in the column of the evaluation of the top of pattern, the measured value and the evaluation based on the criteria described later are described.

### [Table 1]

TABLE 1

| | Carboxylic acid | Evaluation of the top of | |
|---|---|---|---|
| | compound(pKa1) | the pattern wall | |
| Composition 1 | 2-hydroxybenzoic acid(2.97) | less than 1 nm | A |
| Composition 2 | benzoic acid(4.20) | 12 nm | B |
| Composition 3 | 3-hydroxybenzoic acid(3.84) | 40 nm | B |
| Composition 4 | 4-hydroxybenzoic acid(4.54) | 10 nm | B |
| Composition 5 | fumaric acid(3.03) | less than 1 nm | A |
| Comparative | oxalic acid(1.25) | 206 nm | C |
| Composition 1 | | | |
| Comparative | malonic acid(2.83) | 161 nm | C |
| Composition 2 | | | |
| Comparative | succinic acid(4.20) | 76 nm | C |
| Composition 3 | | | |
| Comparative | glutaric acid(4.32) | 52 nm | C |
| Composition 4 | | | |
| Comparative | citric acid(3.09) | 73 nm | C |
| Composition 5 | | | |

### Example of Resist Pattern Formation

Using the coater developer Mark8 (Tokyo Electron), the composition prepared above is dropped onto an 8 cm Si wafer and coated by spinning. This wafer is heated at 140° C. for 90 seconds using a hot plate under atmospheric conditions to form a resist film. When measured by the spectroscopic film thickness measurement system M-1210 (SCREEN), the thickness of the resist film at this point is 10.5 μm.

This resist film is exposed using the KrF stepper FPA3000-EX5 (Canon). The exposed wafer is heated (PEB) at 110° C. for 90 seconds under atmospheric conditions using a hot plate. Then, this resist film is paddle-developed with 2.38 mass % TMAH aqueous solution for 60 seconds, washed with DIW, and spin-dried at 1,000 rpm. As a result, a trench pattern having a line width of 15 μm, a space width of 3 μm and a top width of 9 μm is formed. The line width and space width are measured values at the bottom of the pattern.

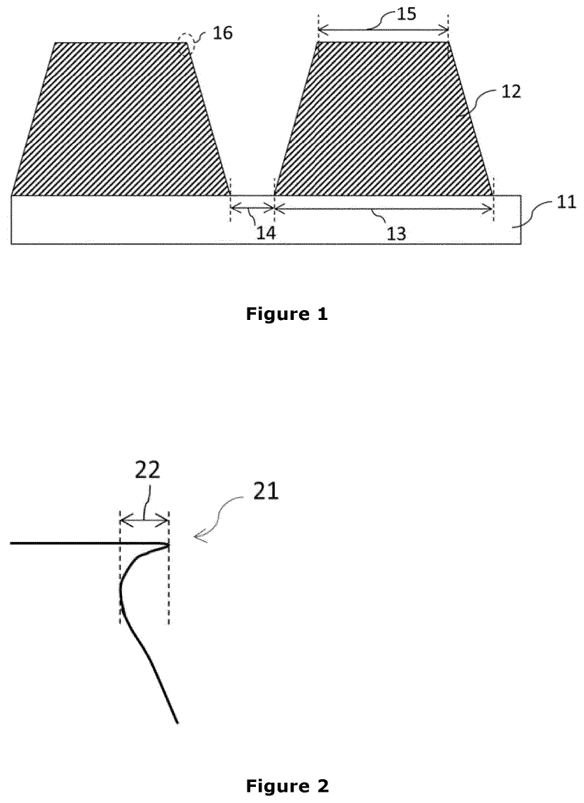

FIG. 1 schematically shows this pattern shape. A resist pattern 12 is formed on a substrate 11, and the line width 13, the space width 14 and the top width 15 are as shown in FIG. 1. FIG. 2 is an enlarged schematic view of the top of pattern wall 16 described later.

The exposure energy (mJ/cm²) used to obtain a pattern of this shape is taken as the sensitivity. When Composition 1 is used, the sensitivity is 108 (mJ/cm²). The sensitivities of Compositions 2 to 5 are described in Table 2. The sensitivity referred here is the sensitivity of the initial composition described later.

### Evaluation of the Top of the Pattern Wall

A slice of the sample that is formed in the resist pattern formation example is prepared, and the vertical cross section of the pattern is observed with a scanning electron microscope (SEM). The degree of being scooped inward from the top of the pattern (the width of bite) is evaluated. In particular, it is explained with reference to FIG. 2. FIG. 2 schematically shows the top of wall 21. A line is drawn perpendicular from the end point of the top of the pattern down to the substrate. A line is drawn perpendicular from the most scooped point on the side surface of the pattern down to the substrate. The distance between each line is taken as the width of bite.

The evaluation criteria are as follows.
A: width of bite is less than 1 nm
B: width of bite is 1 to 50 nm
C: width of bite is larger than 50 nm

The evaluation results are shown in Table 1.

### Evaluation of Aging Stability

Immediately after the preparation of each composition, a trench pattern having a line width of 15 μm, a space width of 3 μm and a top width of 9 μm is formed in the same manner as the above-mentioned resist pattern formation example, and the sensitivity thereof is measured. This is taken as the sensitivity of the initial composition.

Each composition is stored at 40° C. for 30 days. Using these, a trench pattern having a line width of 15 μm, a space width of 3 μm and a top width of 9 μm is formed in the same manner as the resist pattern formation example, and the sensitivity thereof is measured. This is taken as the sensitivity of the aged composition.

(Sensitivity of aged composition)/(sensitivity of initial composition) is calculated and aging stability is evaluated.

The evaluation criteria are as follows.
Stable: sensitivity change is less than 10%
Unstable: sensitivity change is 10% or more

The evaluation results are shown in Table 2.

### Evaluation of Film Loss

Using the coater developer Mark8, the composition is dropped onto an 8 cm Si wafer and coated by spinning. This wafer is heated at 140° C. for 90 seconds using a hot plate under atmospheric conditions to form a resist film. The thickness of the resist film at this point is measured by M-1210, and this is taken as the initial film thickness.

The above formation of the resist film is conducted, and the resist film is further exposed with the KrF stepper FPA3000-EX5. The wafer is subjected to PEB at 110° C. for 90 seconds using a hot plate under atmospheric conditions. This resist film is developed with a 2.38 mass % TMAH aqueous solution for 60 seconds. As a result, a trench pattern having a line width of 15 μm and a space width of 3 μm is formed. This wafer is spin-dried at 1,000 rpm. The thickness of the resist film at this point is measured by M-1210, and this is taken as the post-exposure film thickness.

Following evaluation is made: if the post-exposure film thickness/initial film thickness<99% is satisfied, there is no film loss, and if the post-exposure film thickness/initial film thickness≥99% is satisfied, there is film loss. The evaluation results are shown in Table 2.

### Evaluation of Exposure Latitude (EL)

The composition containing no carboxylic acid compound (C) is prepared as the control, a trench pattern having a line width of 15 μm, a space width of 3 μm and a top width of 9 μm is formed in the same manner as the above-mentioned resist pattern formation example, and the sensitivity thereof is measured (this sensitivity is called the reference sensitivity). Using the compositions containing the carboxylic acid compound (C) shown in Table 2, a trench pattern is formed so as to have a space width±2% (that is, 2.94 to 3.06 μm) as same as the above-mentioned resist pattern formation example, the sensitivity thereof is measured, and the amount of change in sensitivity is calculated.

Assuming that EL=sensitivity change/reference sensitivity×100, the EL of each composition is calculated. The results are shown in Table 2.

### Evaluation of Peeling

A resist pattern is formed in the same manner as the above resist pattern formation example, except that a trench pattern having a line width of 15 μm and a space width of 20 μm is formed. The interface between the Si wafer and the resist wall is observed with a CD-SEM at a magnification of 50 K. If peeling can be confirmed, it is evaluated as present, and if it cannot be confirmed, it is evaluated as none. The evaluation results are shown in Table 2.

### [Table 2]

TABLE 2

| | Carboxylic | | | | | |
|---|---|---|---|---|---|---|
| | acid | Sensitivity | Aging | Film | | |
| | compound | mJ/cm² | stability | loss | EL | Peeling |
| Compo- | 2-hydroxybenzoic | 108 | Stable | No | 33 | No |
| sition 1 | acid | | | | | |
| Compo- | benzoic acid | 108 | Stable | No | 30 | No |
| sition 2 | | | | | | |
| Compo- | 3-hydroxybenzoic | 117 | Stable | No | 28 | No |
| sition 3 | acid | | | | | |
| Compo- | 4-hydroxybenzoic | 133 | Stable | No | 26 | No |
| sition 4 | acid | | | | | |
| Compo- | fumaric acid | 105 | Stable | No | 30 | No |
| sition 5 | | | | | | |

### Preparation of Composition 21

PGME and PGMEA are mixed at a mass ratio of 70:30 (=PGME:PGMEA) to obtain a mixed solvent. Into this mixed solvent (66.0 mass parts), the polymer A1 (33.447 mass parts), the deprotecting agent B1 (0.067 mass parts), the deprotecting agent B2 (0.375 mass parts), the quencher E1 (0.01 mass parts) and the surfactant F1 (0.051 mass parts) are added. Into this, the carboxylic acid compound C1 (2-hydroxybenzoic acid) of 0.015 mass % with respect to the polymer A1 is added and the mixture is stirred at room temperature for 30 minutes to obtain a solution. It is visually confirmed that each component is completely dissolved. The obtained solution is filtered through a 0.05 μm filter to obtain Composition 21.

### Preparation of Compositions 22 to 26

Preparations are conducted in the same manner as the preparation of Composition 21 except that the addition amount of the carboxylic acid compound C1 is changed as shown in Table 3, to obtain Compositions 22 to 26.

### [Table 3]

TABLE 3

| | Addition | | | |
|---|---|---|---|---|
| | amount | | | |
| | (mass % to | Sensitivity | Evaluation of the top of | |
| | Polymer A) | mJ/cm² | the pattern wall | |
| Composition 21 | 0.015 | 105 | 16 nm | B |
| Composition 22 | 0.038 | 100 | 16 nm | B |
| Composition 23 | 0.100 | 97 | 16 nm | B |
| Composition 24 | 0.150 | 102 | less than 1 nm | A |
| Composition 25 | 0.200 | 106 | less than 1 nm | A |
| Composition 26 | 0.600 | 138 | less than 1 nm | A |

### Formation of Resist Pattern and Evaluation of Top of the Pattern Wall

Formation of the resist pattern is conducted in the same manner as described above, and a trench pattern having a line width of 15 μm and a space width of 3 μm is formed. Each sensitivity thereof is shown in Table 3. Similarly, evaluation of the top of pattern wall is also conducted, and the evaluation results are shown in Table 3.

### Preparation of Composition 31

The same preparation as that of Composition 21 is conducted except that the carboxylic acid compound C₁ is changed to fumaric acid and the addition amount thereof is changed to 0.0126 mass % with respect to the polymer A1 to obtain Composition 31.

The amounts of the carboxylic acid compound C added each in Example 21 (2-hydroxybenzoic acid of 0.015 mass % with respect to the polymer A) and Example 31 (fumaric acid of 0.126 mass % with respect to the polymer A) are equimolar in each composition.

### Preparation of Compositions 32 to 36

The same preparations as that of Composition 31 are conducted except that the addition amount of fumaric acid is changed as shown in Table 4 to obtain Compositions 32 to 36.

### [Table 4]

TABLE 4

| | Addition | | | |
|---|---|---|---|---|
| | amount | | | |
| | (mass % to | Sensitivity | Evaluation of the top of | |
| | Polymer A) | mJ/cm² | the pattern wall | |
| Composition 31 | 0.0126 | 104 | 15 nm | B |
| Composition 32 | 0.032 | 94 | less than 1 nm | A |
| Composition 33 | 0.084 | 98 | less than 1 nm | A |
| Composition 34 | 0.126 | 99 | less than 1 nm | A |
| Composition 35 | 0.168 | 101 | less than 1 nm | A |
| Composition 36 | 0.504 | 112 | less than 1 nm | A |

### Formation of Resist Pattern and Evaluation of the Top of Pattern Wall

The resist pattern is formed in the same manner as described above, and a trench pattern having a line width of 15 μm and a space width of 3 μm is formed. Each sensitivity is shown in Table 4. Similarly, evaluation of the top of pattern wall is conducted, and the evaluation results are shown in Table 4.

### EXPLANATION OF SYMBOLS

11. substrate
12. resist pattern
13. line width
14. space width
15. top width
16. top of pattern wall
21. top of wall
22. width of bite

1.-15. (canceled)

16. A thick film resist composition comprising a polymer (A), a deprotecting agent (B), a C₄₋₁₂ carboxylic acid compound (C) and a solvent (D),
wherein
the resist film formed from the thick film resist composition has a film thickness of 0.8 to 20 μm;
the carboxylic acid compound (C) is an unsaturated hydrocarbon comprising 1, 2 or 3 carboxy groups; and
the solvent (D) comprises an organic solvent (D1).

17. The composition according to claim 16, wherein the carboxylic acid compound (C) is an aromatic carboxylic acid (C-1) represented by the formula (c-1) or an aliphatic carboxylic acid (C-2) represented by the formula (c-2): 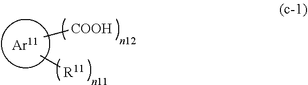
where
Ar¹¹ is a C₅₋₁₀ aromatic hydrocarbon ring,
R¹¹ is OH or NH₂,
n11 is 0 or 1, and n12 is 0, 1 or 2; 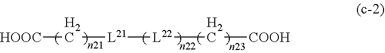
where
L²¹ is —C═C— or —C≡C—,
L²² is —C═C— or —C≡C—,
n21 is 0, 1, 2 or 3, n22 is 0 or 1, and n23 is 0, 1, 2 or 3.

18. The composition according to claim 16, further comprising a quencher (E)).

19. The composition according to claim 16, further comprising a quencher (E):
which is an amine compound (E1) or a carboxylate (E2).

20. The composition according to claim 16, wherein the carboxylic acid compound (C) has a pKa1 (H₂O) of 1.00 to 6.00.

21. The composition according to claim 16, wherein the solvent (D) is selected from the group consisting of ethylene glycol monoalkyl ethers, ethylene glycol monoalkyl ether acetates, propylene glycol monoalkyl ethers, propylene glycol monoalkyl ether acetates, lactates, aromatic hydrocarbons, amides and lactones.

22. The composition according to claim 16, wherein the polymer (A) comprises a repeating unit selected from the group consisting of repeating units represented by the formulae (P-1), (P-2), (P-3) and (P-4): 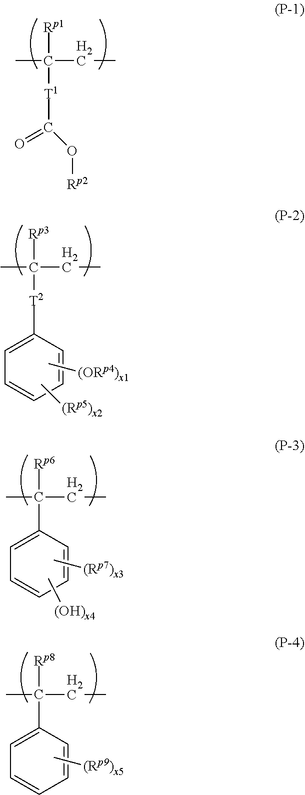
where
R^{p1}, R^{p3}, R^{p6} and R^{p8} are each independently hydrogen or C₁₋₄ alkyl,
R^{p2} and R^{p4} are each independently linear, branched or cyclic, C₃₋₁₅ alkyl (where the alkyl can be substituted with fluorine and —CH₂— in the alkyl can be replaced with —O—),
T¹ and T² are each independently a single bond or a C₁₋₁₂ linking group,
R^{p5}, R^{p7} and R^{p9} are each independently C₁₋₅ alkyl (where —CH₂— in the alkyl can be replaced with —O—),
x1 is 1 to 3,
x2, x3 and x5 are each independently 0 to 2, and
x4 is 1 to 2.

23. The composition according to claim 16, wherein
the deprotecting agent (B) is represented by the formula (B-1) or the formula (B-2):
Bⁿ⁺cation Bⁿ⁻anion (B-1)
wherein
Bⁿ⁺cation consists of at least one cation selected from the group consisting of a cation represented by the formula (BC1), a cation represented by the formula (BC2) and a cation represented by the formula (BC3), and is n valent as a whole (where n is 1 to 3), and
Bⁿ⁻anion consists of at least one anion selected from the group consisting of an anion represented by the formula (BA1), an anion represented by the formula (BA2), an anion represented by formula (BA3) and an anion represented by the formula (BA4), and is n valent as a whole: 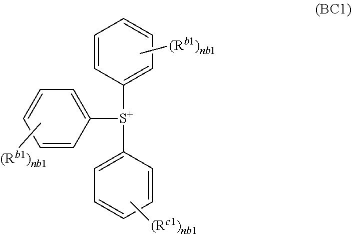
where
R^{b1} is each independently C₁₋₆ alkyl, C₁₋₆ alkoxy, C₆₋₁₂ aryl, C₆₋₁₂ arylthio or C₆₋₁₂ aryloxy, and
nb1 is each independently 0, 1, 2 or 3; 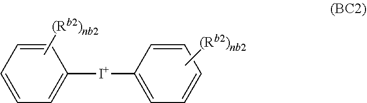
where
R^{b2} is each independently C₁₋₆ alkyl, C₁₋₆ alkoxy or C₆₋₁₂ aryl, and
nb2 is each independently 0, 1, 2 or 3; 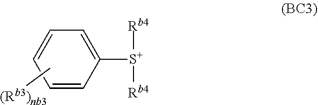
where
R^{b3} is each independently C₁₋₆ alkyl, C₁₋₆ alkoxy or C₆₋₁₂ aryl,
R^{b4} is each independently C₁₋₆ alkyl, and
nb3 is each independently 0, 1, 2 or 3; 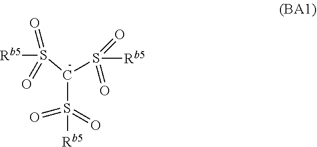
where
R^{b5} is each independently fluorine-substituted C₁₋₆ alkyl, or C₁₋₆ alkyl;
R^{b6}—SO₃⁻ (BA2)
where
R^{b6} is fluorine-substituted C₁₋₆ alkyl, fluorine-substituted C₁₋₆ alkoxy, fluorine-substituted C₆₋₁₂ aryl, fluorine-substituted C₂₋₁₂ acyl or fluorine-substituted C₆₋₁₂ alkoxyaryl; 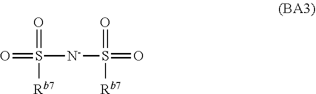
where
R^{b7} is each independently fluorine-substituted C₁₋₆ alkyl, fluorine-substituted C₁₋₆ alkoxy, fluorine-substituted C₆₋₁₂ aryl, fluorine-substituted C₂₋₁₂ acyl or fluorine-substituted C₆₋₁₂ alkoxyaryl, where two R^{b7} can be bonded to each other to form a fluorine-substituted heterocyclic structure; 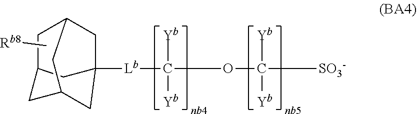
where
R^{b8} is hydrogen, C₁₋₆ alkyl, C₁₋₆ alkoxy or hydroxy,
L^{b} is carbonyl, oxy or carbonyloxy,
Y^{b} is each independently hydrogen or fluorine,
nb4 is an integer of 0 to 10, and
nb5 is an integer of 0 to 21; 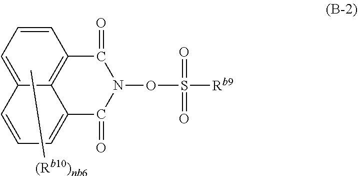
where
R^{b9} is fluorine-substituted C₁₋₅ alkyl,
R^{b10} is each independently C₃₋₁₀ alkenyl or alkynyl (where CH₃— in the alkenyl and alkynyl can be replaced with phenyl, and —CH₂— in the alkenyl and alkynyl can be replaced with at least one of —C(═O)—, —O— or phenylene), C₂₋₁₀ thioalkyl, C₅₋₁₀ saturated heterocycle, and nb6 is 0, 1 or 2.

24. The composition according to claim 16, further comprising a surfactant (F).

25. The composition according to claim 16, further comprising a surfactant (F): and an additive (G).

26. The composition according to claim 18, further comprising a surfactant (F): and an additive (G).

27. The composition according to claim 25, wherein the additive (G) is at least one selected from the group consisting of a surface smoothing agent, a plasticizer, a dye, a contrast enhancer, an acid, a base, a radical generator, a substrate adhesion enhancer and an antifoaming agent.

28. The composition according to claim 16, wherein the content of the polymer (A) is 20 to 45 mass % based on the composition and the content of the carboxylic acid compound (C) is 0.01 to 5 mass % based on the polymer (A):
the content of the deprotecting agent (B) is 0.05 to 10 mass % based on the polymer (A);
the content of the solvent (D) is 50 to 80 mass % based on the composition; and
the content of the organic solvent (D1) is 80 to 100 mass % based on the solvent (D).

29. The composition according to claim 26, wherein the content of the polymer (A) is 20 to 45 mass % based on the composition and the content of the carboxylic acid compound (C) is 0.01 to 5 mass % based on the polymer (A):
the content of the deprotecting agent (B) is 0.05 to 10 mass % based on the polymer (A);
the content of the solvent (D) is 50 to 80 mass % based on the composition;
the content of the organic solvent (D1) is 80 to 100 mass % based on the solvent (D).
the content of the quencher (E) is 0.001 to 5 mass % based on the polymer (A);
the content of the surfactant (F) is 0.01 to 5 mass % based on the polymer (A); and
the content of the additive (G) is 0.01 to 10 mass % based on the polymer (A).

30. The composition according to claim 16, which is a thick film chemically amplified resist composition:
the composition is a thick film KrF chemically amplified resist composition,
the composition is a thick film positive type chemically amplified resist composition; or
the composition is a thick film KrF positive type chemically amplified resist composition.

31. A method for manufacturing a resist film comprising the following steps:
(1) applying the composition according to claim 16 above a substrate; and
(2) heating the composition to form a resist film having a film thickness of 0.8 to 20 μm.

32. A method for manufacturing a resist pattern comprising the following steps:
forming a resist film by the method according to claim 31;
(3) exposing the resist film; and
(4) developing the resist film.

33. The method for manufacturing a resist pattern according to claim 32, wherein the distance between the perpendicular line drawn from the end point of the top of the resist pattern down to the substrate and the perpendicular line drawn from the most scooped point on the side surface of the resist pattern down to the substrate is 50 nm or less.

34. A method for manufacturing a processed substrate comprising the following steps:
forming a resist pattern by the method according to claim 32; and
(5) processing using the resist pattern as a mask:
preferably, in the step (5), the underlayer film or the substrate is processed.

35. A method for manufacturing a device comprising the method according to claim 32:
a step of forming a wiring on the processed substrate is further comprised.
